(19) United States
(12) Patent Application Publication
(10) Pub. No.: US 2010/0289053 A1
(43) Pub. Date: Nov. 18, 2010

(54) SEMICONDUCTOR LIGHT EMITTING ELEMENT AND METHOD OF MANUFACTURING THE SAME, AND SEMICONDUCTOR ELEMENT AND METHOD OF MANUFACTURING THE SAME

(75) Inventor: Naoki Hirao, Kanagawa (JP)

Correspondence Address: K&L Gates LLP, P. O. BOX 1135, CHICAGO, IL, 60690, US

(73) Assignee: SONY CORPORATION, Tokyo (JP)

(21) Appl. No.: 12/770,967

(22) Filed: Apr. 30, 2010

(30) Foreign Application Priority Data
May 13, 2009 (JP) P2009-116266

(51) Int. Cl. H01L 33/40; H01L 21/283

(52) U.S. Cl. 257/99; 438/46; 438/22; 257/E33.066; 257/E21.159

(57) ABSTRACT

Disclosed herein is a method of manufacturing a semiconductor light emitting element, including the steps of: forming a nickel thin film having a thickness of one atomic layer to 10 nm so as to contact a semiconductor layer forming a light emitting element structure; and forming a silver electrode on the nickel thin film.

### CROSS REFERENCES TO RELATED APPLICATIONS

The present application claims priority to Japanese Priority Patent Application JP 2009-116266 filed in the Japan Patent Office on May 13, 2009, the entire content of which is hereby incorporated by reference.

### BACKGROUND

The present application relates to a semiconductor light emitting element and a method of manufacturing the same, and a semiconductor element and a method of manufacturing the same, and more particularly is suitable for being applied to a semiconductor light emitting element using a silver (Ag) electrode, for example, a light emitting diode.

In a light emitting diode using a GaN system semiconductor and the like, an Ag electrode is used as an electrode formed in a semiconductor layer in many cases. However, the Ag electrode involves the following problems.

1. The pure Ag essentially has a low resistance against oxidation and sulfuration (easy to react with oxygen and sulfur). Thus, the pure Ag is easily influenced by uptake of oxygen and sulfur from an exposed environment, and a reflectivity thereof is deteriorated. In particular, the Ag film which is formed by utilizing a vacuum evaporation method and which is generally used in electrode formation is more remarkably deteriorated because of imperfection of a grain boundary structure formed in the Ag film.

2. The Ag film has a low heat-resisting property. Thus, optical characteristics and electrical characteristics thereof are readily changed even when being heated at a temperature of about 300 to 400° C.

3. Although Ag is a noble metal which is hardly ionized, as will be described later, Ag is ionized when moisture exists, and ionized Ag migrates to cause a failure in a device.

4. Although a GaN system light emitting diode is generally encapsulated with a resin, the case where small amounts of moisture and sulfur content contained in the resin contribute to the deterioration of characteristics of the GaN system light emitting diode is frequently observed.

FIG. 11 shows an example of a structure of an existing GaN system light emitting diode. As shown in FIG. 11, an Ag electrode 102 is formed so as to contact a p-type semiconductor layer of a semiconductor layer 101 including an n-type semiconductor layer, an active layer and the p-type semiconductor layer. Also, a metallic film 103 for connection is formed on the Ag electrode 102. Also, a lower wiring 104 is formed on the n-type semiconductor layer of the semiconductor layer 101.

In such a GaN system light emitting diode, the migration of the ionized Ag from the Ag electrode 102 is caused in the manner as will be described below. As shown in FIG. 12, due to a difference in electric potential between the Ag electrode 102 and the lower wiring 104, and the existence of water adsorbed from the ambient atmosphere to a surface of the Ag electrode 102, ionic dissociation is caused in accordance with the following reaction formulas:

Ag→Ag⁺

H₂O→H⁺+OH⁻

Ag⁺ and OH⁻ thus created create AgOH in the Ag electrode 102, and AgOH is deposited. AgOH thus deposited is decomposed in accordance with the following reaction formula, and turns into Ag₂O, in the Ag electrode 102, which is in turn dispersed in a colloid:

2AgOH=Ag₂O+H₂O

The subsequent hydration reaction is expressed by the following chemical reaction formulas:

Ag₂O+H₂O=2AgOH

2AgOH=2Ag⁺+OH⁻

When this hydration reaction proceeds, Ag⁺ moves to the lower wiring 104, and dendrite-like deposition of Ag proceeds. In addition, finally, the Ag electrode 102 and the lower wiring 104 are short-circuited to cause the failure of the GaN system light emitting diode.

For the purpose of preventing the above migration of Ag, there are used a method of using an alloy of Ag and any other suitable metal as an electrode material, and a method of encapsulating the electrode with a resin. However, the case where the alloy of Ag and any other suitable metal is used as the electrode material involves disadvantages such that not only the material is costly as compared with the case of use of Ag in many cases, but also the migration suppressing effect is low. In addition, a method of controlling the migration of Ag by suppressing the moisture, or the like is known as the method of encapsulating the electrode with the resin. With this method, however, control for moisture absorption, prevention of reduction of transparency, prevention of salt damage, prevention of debasement of a pattern precision, and the like need to be realized depending on use applications. Various kinds of methods are used in order to solve these problems. A method of encapsulating an electrode with a protective film made of a metal (barrier metal) for suppressing migration of Ag is known as one of those methods. This method, for example, is described in Japanese Patent Laid-Open Nos. 2007-80899 and 2007-184411. One example is shown in FIG. 13, and another example is shown in FIG. 14.

In a light emitting diode shown in FIG. 13, an Ag electrode 202 is formed so as to contact a p-type semiconductor layer of a semiconductor layer 201 including an n-type semiconductor layer, an active layer, and the p-type semiconductor layer. In addition, a protective film 203 made of a barrier metal is formed so as to cover an upper surface and a side surface of the Ag electrode 202. Also, a lower wiring 204 is formed on the n-type semiconductor layer of the semiconductor layer 201.

In addition, in a light emitting diode shown in FIG. 14, an Ag electrode 302 is formed so as to contact a p-type semiconductor layer of a semiconductor layer 301 including an n-type semiconductor layer, an active layer, and the p-type semiconductor layer. Also, a metallic film 303 for connection is formed on the Ag electrode 302. A protective film 304 made of a barrier metal is formed so as to cover an upper surface of the metallic film 303, and side surfaces of the Ag electrode 302 and the metallic film 303. A metallic film 305 for connection is formed on the protective film 304. Also, a lower wiring 306 is formed on the n-type semiconductor layer of the semiconductor layer 301.

### SUMMARY

With the light emitting diodes shown in FIGS. 13 and 14, respectively, the moisture is suppressed by the protective films 203 and 304, and an equipotential plane is formed, whereby strengths of electric fields applied to the Ag electrodes 202 and 302, respectively, are either reduced or made zero, thereby suppressing the migration of Ag. This method has an advantage that the effect of suppressing the migration of Ag is very large. However, each of sizes of the protective films 203 and 304 for covering the Ag electrodes 202 and 302, and the like need to be made several micron meters larger than each of the sizes of the Ag electrodes 202 and 302 from a request for an alignment precision.

However, when the size of the light emitting diode is minute (for example, equal to or smaller than 50 μm), the sizes of the protective films 203 and 304 covering the Ag electrodes 202 and 302, respectively, can not be disregarded for the sizes of the Ag electrodes 202 and 302. In other words, in the case where the size of the light emitting diode is determined in advance, when the protective films 203 and 304 are formed, the sizes of the Ag electrodes 202 and 302 are compelled to be made small all the more. In the GaN system light emitting diode or the like, for the purpose of enhancing the light taking-out efficiency, the Ag electrodes 202 and 302 are used as reflecting mirrors, respectively, in many cases. As a result, when the sizes of the Ag electrodes 202 and 302 become small, quantities of light reflected by the Ag electrodes 202 and 302 are reduced. In addition, the absorption of the lights in the portions of the protective films 203 and 304 contacting the semiconductor layers 201 and 301 is caused. As a result, the efficiency of taking out the light from the light emitting diode is reduced, and the light emission efficiency is in turn reduced.

In addition, when the protective films 203 and 304 are formed, in processes for manufacturing the light emitting diode, a lithography process for forming the protective films 203 and 304 is also required in addition to a lithography process for forming the Ag electrodes 202 and 302. As a result, there is encountered such a problem that it takes a lot of time to manufacture the light emitting diode, and thus the manufacture cost becomes high.

The present application has been made in order to solve the problems described above, and it is therefore desirable to provide a semiconductor light emitting element such as a light emitting diode which has a long life and a high reliability, is inexpensive, and has excellent characteristics, and a method of manufacturing the same.

Also, it is desirable to provide a semiconductor element which has a long life and a high reliability, is inexpensive, and has excellent characteristics, and a method of manufacturing the same.

It has been discovered that it is very effective that when the silver electrode is formed on the semiconductor layer, the silver electrode is not formed so as to directly contact the semiconductor layer, but, firstly, a nickel film having a very small thickness, specifically, a thickness of 10 nm or less is formed so as to contact the semiconductor layer, and the silver electrode is formed on the nickel film, according to an embodiment. According to this method, the problems described above can be solved all at once.

In order to attain the desire described above, according to an embodiment of the present application, there is provided a method of manufacturing a semiconductor light emitting element including the steps of: forming a nickel thin film having a thickness of one atomic layer to 10 nm so as to contact a semiconductor layer forming a light emitting element structure; and forming a silver electrode on the nickel thin film.

According to another embodiment, there is provided a semiconductor light emitting element including: a semiconductor layer forming a light emitting element structure; a nickel thin film having a thickness of one atomic layer to 10 nm and contacting the semiconductor layer; and a silver electrode formed on the nickel thin film.

In the embodiments, the thickness of the nickel thin film is preferably equal to or smaller than 2 nm, and is typically equal to or smaller than 1 nm. The nickel thin film and the silver electrode may directly contact each other, or any other suitable metallic film having one layer, or two or more layers may be formed between the nickel thin film and the silver electrode. Preferably, for the purpose of preventing the semiconductor layer and the silver electrode from directly contacting each other, the silver electrode is formed so as not to protrude to the outside of the nickel thin film. The semiconductor layer forming the light emitting element structure may be made of any of various kinds of semiconductors such as a III-V compound semiconductor. For example, in this case, the semiconductor layer forming the light emitting element structure is a nitride system III-V compound semiconductor layer. In general, the nitride system III-V compound semiconductor is composed of at least one kind of group III element selected from the group consisting of Ga, Al, In, and B, and a group V element containing therein at least N, and further containing therein either As or P as the case may be. As concrete examples of the nitride system III-V compound semiconductor are GaN, InN, AlN, AlGaN, InGaN, AlGaInN, and so on. The semiconductor layer forming the light emitting element structure includes an n-type semiconductor layer, an active layer, and a p-type semiconductor layer. The nickel thin film is formed so as to contact the p-type semiconductor layer, and the Ag electrode is formed on the nickel thin film. Although the semiconductor light emitting element is typically a light emitting diode, it may be a semiconductor laser instead.

According to still another embodiment, there is provided a method of manufacturing a semiconductor element including the steps of: forming a nickel thin film having a thickness of one atomic layer to 10 nm so as to contact a semiconductor layer forming an element structure; and forming a silver electrode on the nickel thin film.

According to yet another embodiment, there is provided a semiconductor element including: a semiconductor layer forming an element structure; a nickel thin film having a thickness of one atomic layer to 10 nm and contacting the semiconductor layer; and a silver electrode formed on the nickel thin film.

In addition to the semiconductor light emitting element such as the light emitting diode, an electron traveling element such as a field-effect transistor (FET) is included in the semiconductor element.

The description given in relation to the present embodiments of the semiconductor light emitting element described above and the method of manufacturing the same is established in the invention of the semiconductor element and the method of manufacturing the same.

In an embodiment constituted as described above, the migration of silver from the silver electrode can be effectively suppressed by the nickel thin film having the thickness of one atomic layer to 10 nm and formed between the semiconductor layer and the silver electrode. In this case, the processes for manufacturing the semiconductor light emitting element or the semiconductor element can be simplified all the more because the protective film made of the barrier metal needs not to be formed as with the related art. In addition, since the protective film needs not to be formed, the size of the silver electrode, therefore, the area of the silver electrode can be made sufficiently large all the more, and thus the quantity of light reflected by the silver electrode can be made sufficiently much. In addition thereto, in the semiconductor light emitting element such as the light emitting diode, there is no absorption of the light in the contact portion between the protective film and the semiconductor layer.

As set forth hereinabove, according to the embodiment, it is possible to provide the semiconductor light emitting element which has the long life and the high reliability, is inexpensive, and has the excellent characteristics, and the method of manufacturing the same as well as the semiconductor element which has the long life and the high reliability, is inexpensive, and has the excellent characteristics, and the method of manufacturing the same.

Additional features and advantages are described herein, and will be apparent from the following Detailed Description and the figures.

### BRIEF DESCRIPTION OF THE FIGURES

FIG. 1 is a cross sectional view showing a structure of a GaN type light emitting diode as a semiconductor light emitting element according to a first embodiment;

FIGS. 2A and 2B are respectively enlarged cross sectional views of main portions of the GaN type light emitting diode according to the first embodiment;

FIG. 3 is a cross sectional view showing a structure and a size of a GaN system light emitting diode according to an example of the first embodiment;

FIG. 4 is a graph showing results of carrying out the aging for the GaN system light emitting diode according to the example of the first embodiment;

FIG. 5 is a graph showing results of measuring current-voltage characteristics of the GaN system light emitting diode according to the example of the first embodiment;

FIG. 6 is a graph showing results of measuring current-light output characteristics of the GaN system light emitting diode according to the example of the first embodiment;

FIG. 7 is a cross sectional view showing a structure and a size of a GaN system light emitting diode according to a comparative example;

FIG. 8 is a graph showing results of carrying out the aging for the GaN system light emitting diode according to the comparative example;

FIG. 9 is a graph showing results of measuring current-voltage characteristics of the GaN system light emitting diode according to the comparative example;

FIG. 10 is a graph showing results of measuring current-light output characteristics of the GaN system light emitting diode according to the comparative example;

FIG. 11 is a cross sectional view showing a structure of a first example of an existing light emitting diode using an Ag electrode;

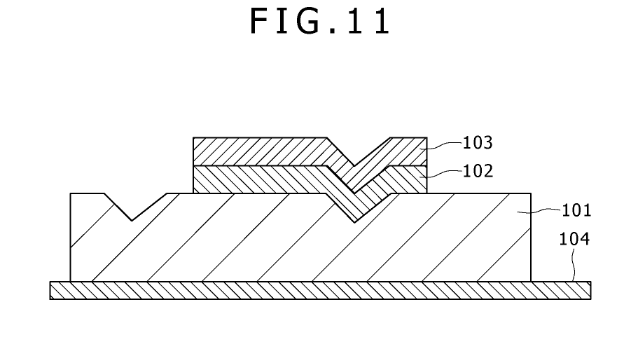

FIG. 12 is a cross sectional view explaining a problem about short-circuit caused by migration of Ag from the Ag electrode in the existing light emitting diode using the Ag electrode;

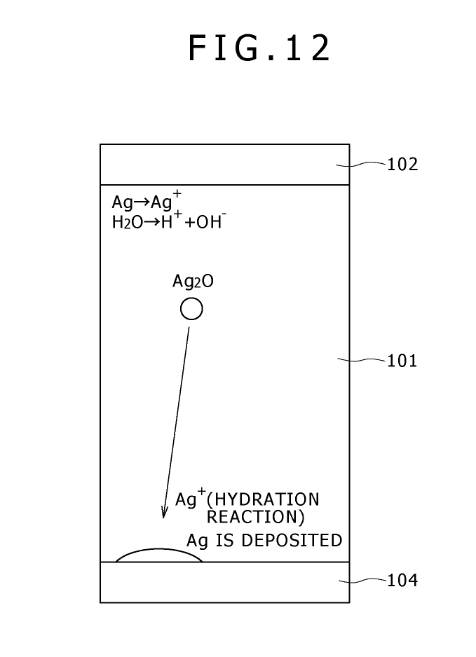

FIG. 13 is a cross sectional view showing a structure of a second example of an existing light emitting diode using an Ag electrode; and

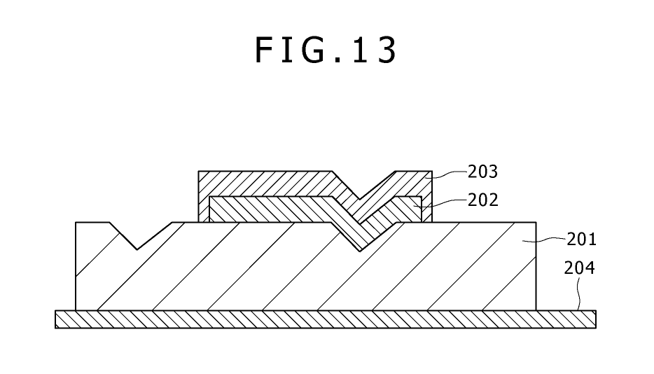

FIG. 14 is a cross sectional view showing a structure of a third example of an existing light emitting diode using an Ag electrode.

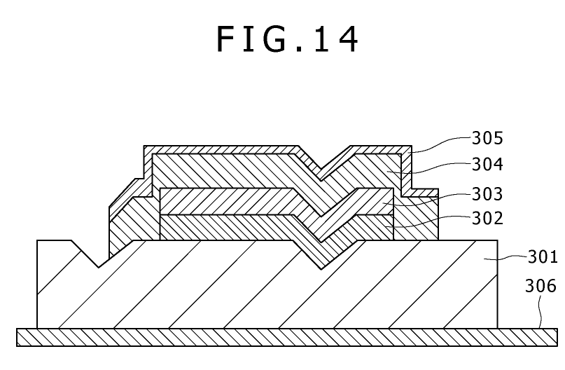

### DETAILED DESCRIPTION

The present application will be described in detail hereinafter with reference to the accompanying drawings according to an embodiment. It is noted that the description will be given below in accordance with the following order.

1. First Embodiment (Light Emitting Diode and a Method of Manufacturing the Same)

2. Second Embodiment (Light Emitting Diode and a Method of Manufacturing the Same)

### 1. First Embodiment

[Light Emitting Diode and a Method of Manufacturing the Same]

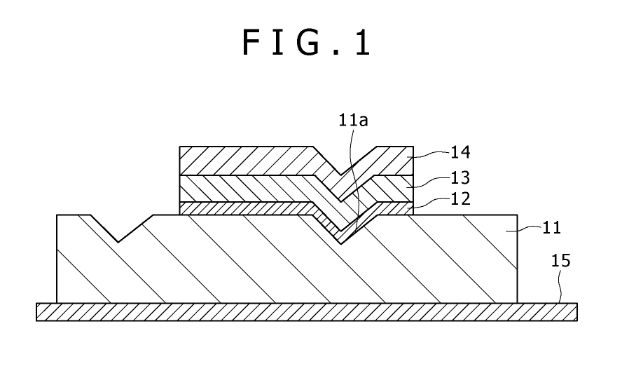

FIG. 1 is a cross sectional view showing a structure of a GaN system light emitting diode as a semiconductor light emitting element according to a first embodiment.

As shown in FIG. 1, in this GaN system light emitting diode, a Ni super-thin film 12 is provided so as to contact a semiconductor layer 11 forming a light emitting diode structure, and an Ag electrode 13 and a metallic film 14 for connection are provided in order on the Ni super-thin film 12. The Ag electrode 13 forms a p-side electrode (anode electrode). A thickness of the Ni super-thin film 12 is equal to or larger than that of one atomic layer, and is equal to or smaller than 10 nm, is preferably equal to or smaller than 2 nm, and is typically equal to or smaller than 1 nm. The Ni super-thin film 12 having the thickness of 10 nm or less is approximately transparent to a light such as a visible light, and thus does not impair a light reflectivity performance of the Ag electrode 13. The semiconductor layer 11 includes an n-type semiconductor layer, an active layer formed on the n-type semiconductor layer, and a p-type semiconductor layer formed on the active layer. The Ni super-thin film 12 contacts the p-type semiconductor layer of the semiconductor layer 11. A lower wiring 15 is formed so as to contact the n-type semiconductor layer of the semiconductor layer 11. The lower wiring 15 serves as an n-side electrode (cathode electrode) as well. It is noted that although the case where a pit 11a generated with a though displacement within the semiconductor layer 11 as an origination is formed on a surface of the semiconductor layer 11 is shown as an example in FIG. 1, the present invention is by no means limited thereto. Thus, presence or absence of formation of the pit 11a is independent of the essence of the present application.

The semiconductor layer 11, for example, is a nitride system III-V compound semiconductor layer, typically, a GaN system semiconductor layer. Specifically, the GaN system semiconductor layer, for example, includes an n-type GaN cladding layer, an active layer formed on the n-type GaN cladding layer, and a p-type cladding layer formed on the active layer. The active layer, for example, has a Ga₁₋ₓInₓN/Ga_{1-y}In_{y}N multi-quantum well structure (MQW) having a Ga₁₋ₓInₓN layer and a Ga_{1-y}In_{y}N layer (y>x, x≦0<1) as a barrier layer and a well layer, respectively. An composition, y, of the Ga_{1-y}In_{y}N layer is selected in accordance with a light emission wavelength of the light emitting diode. For example, the composition, y, of the Ga_{1-y}In_{y}N layer is about 11% when the light emission wavelength is 405 nm, is about 18% when the light emission wavelength is 450 nm, and is about 24% when the light emission wavelength is 520 nm.

The existing known metallic film can be used as the metallic film 14 for connection, and is selected as may be necessary. For example, a multilayer film having a Ni/Pt/Au structure in which a nickel (Ni) film, a platinum (Pt) film and a gold (Au) film are laminated in order, or the like is used as the metallic film 14 for connection. Also, the existing known metallic film can be used as the lower wiring 15, and is selected as may be necessary. For example, a metallic lamination film having a Ti/Pt/Au structure in which a titanium (Ti) film, a platinum (Pt) and a gold (Au) film are laminated in order, or the like is used as the lower wiring 15.

In a phase of drive of this GaN system light emitting diode, a forward voltage is applied across the Ag electrode 13 as a p-side electrode, and the lower wiring 15, so that a light is emitted from the active layer. The light emitted from the active layer circulates within the semiconductor layer 11 while it is repeatedly reflected within the inside of the semiconductor layer 11. At this time, the light directed toward the Ag electrode 13 reaches the Ag electrode 13 without being absorbed by the Ni super-thin film 12. Therefore, about 100% of that light is reflected by the Ag electrode 13, and thus that light is directed toward the lower surface of the semiconductor layer 11. As a result, the circulating light within the semiconductor layer 11 is efficiently taken out from the lower surface of the semiconductor layer 11 to the outside.

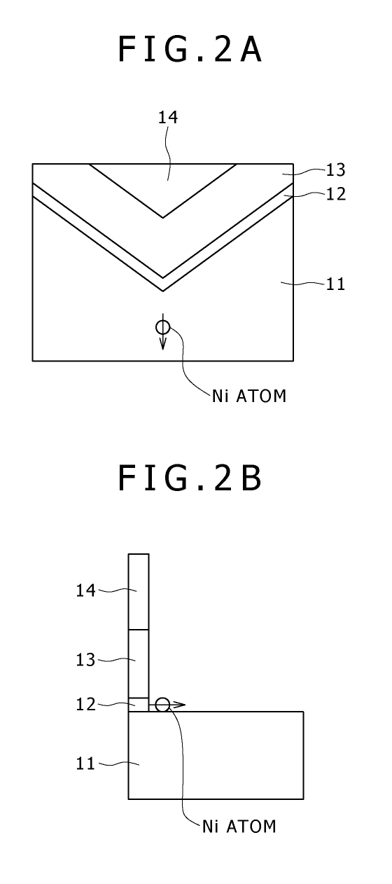

In the phase of the driving of the GaN system light emitting diode, it is possible to prevent the short-circuit, between the Ag electrode 13 and the lower wiring 15, caused by the migration of Ag from the Ag electrode 13 in the manner as described above. As shown in FIG. 2A, Ni atoms move from the Ni super-thin film 12 formed between the semiconductor layer 11 and the Ag electrode 13 to the semiconductor layer 11 side through the migration (the electro-migration and the ion-migration). At this time, the migration of the Ag atoms from the Ag electrode 13 is blocked by the Ni super-thin film 12. The reason that the migration of the Ag atoms from the Ag electrode 13 is not caused, but the migration of the Ni atoms from the Ni super-thin film 12 is caused in such a manner is thought as follows. That is, a standard electric electrode potential of Ni is −0.25 V, whereas a standard electrode electric potential of Ag is 0.798 V which is much higher than the standard electrode electric potential of Ni of −0.25 V. The Ni atoms do not substantially reach the lower wiring 15 because the movement speed of the Ni atom within the semiconductor layer 11 is very slow. Although as shown in FIG. 2B, the Ni atoms move from the Ni super-thin film 12 to the surface as well of the semiconductor layer 11, the Ni atoms do not also reach the lower wiring 15.

Next, a description will now be given with respect to a method of manufacturing the GaN system light emitting diode of the first embodiment.

Firstly, the semiconductor layer 11 is epitaxially grown on a predetermined substrate (not shown). The semiconductor layer 11 can be epitaxially grown by utilizing any one of the existing known various kinds of methods such as a metal organic chemical vapor deposition (MOCVD) and a molecular beam epitaxy (MBE).

Next, the semiconductor layer 11 is patterned into a predetermined planar shape by utilizing a dry etching method or the like.

Next, a resist pattern (not shown) having a predetermined planar shape is formed on a surface of the substrate through the semiconductor layer 11 having the predetermined planar shape and formed on the surface of the substrate by utilizing a lithography process. Next, the Ni super-thin film 12, the Ag electrode 13 and the metallic film 14 for connection are formed in order over the entire surface of the substrate by utilizing a vacuum evaporation method, a sputtering method or the like. Next, the resist pattern is removed away together with the Ni super-thin film 12, the Ag electrode 13 and the metallic film 14 for connection which are formed on the resist pattern (liftoff).

Next, a surface on the side of the metallic film 14 for connection is stuck to a supporting substrate (not shown), and the semiconductor layer 11 is peeled off from the substrate.

Next, the lower wiring 15 is formed on the n-type semiconductor layer of the semiconductor layer 11.

By successively carrying out the processes described above, the desired GaN system light emitting diode is manufactured. The GaN system light emitting diode manufactured in such a manner may be used as a single element or may be stuck to another substrate, or may be transferred, or wiring connection may be carried out for the GaN system light emitting diode in accordance with the use application.

### Example

A GaN system light emitting diode was manufactured in the manner as will be described below.

Firstly, a sapphire substrate, for example, having a C+orientation as a principal surface, and having a thickness of 430 μm is prepared, and a surface of the sapphire substrate is cleaned by carrying out thermal cleaning or the like.

Next, firstly, a GaN buffer layer (not shown), for example, having a thickness of 1 μm is grown on the sapphire substrate at a low temperature of, for example, about 500° C. by utilizing the MOCVD method, and the temperature is then made to rise up to about 1,000° C. to crystallize the GaN buffer layer.

Subsequently, an n-type GaN cladding layer, an active layer having a Ga₁₋ₓInₓN/Ga_{1-y}In_{y}N MQW structure, and a p-type GaN cladding layer are grown in order on the GaN buffer layer. The n-type GaN cladding is doped with, for example, silicon (Si) as an n-type impurity. The p-type GaN cladding layer is doped with, for example, magnesium (Mg) as a p-type impurity. Here, the n-type GaN cladding layer is grown at a temperature of, for example, about 1,000° C., the active layer is grown at a temperature of, for example, about 750° C., and the p-type GaN cladding layer is grown at a temperature of, for example, about 900° C. In addition, the n-type GaN cladding layer, for example, is grown within a hydrogen gas atmosphere, the active layer, for example, is grown within a nitrogen gas atmosphere, and the p-type GaN cladding layer, for example, is grown within a hydrogen gas atmosphere.

The growth raw materials for the GaN system semiconductor layer described above are as follows. Trimethylgarium ((CH₃)₃Ga: TMG), for example, is used as the raw material for Ga. Trimethylaluminum ((CH₃)₃Al: TMA), for example, is used as the raw material for Al. Trimethylindium ((CH₃)₃In: TMI), for example, is used as the raw material for In. Also, ammonia (NH₃), for example, is used as the raw material for N. With regard to a dopant, silane (SiH₄), for example, is used as the n-type dopant. Also, either bis(methylcyclopentadienyl) magnesium ((CH₃C₅H₄)₂Mg) or bis(cyclopentadienyl) magnesium ((C₅H₅)₂Mg), for example, is used as a p-type dopant.

Next, the sapphire substrate on which the GaN system semiconductor layer is grown in the manner described above is taken out from an MOCVD system.

Next, after the semiconductor layer 11 is selectively etched by an utilizing reactive ion etching (RIE) method, for example, using Cl₂ system gas as etching gas with a resist pattern (not shown) as a mask, the resist pattern is removed away.

Next, a resist pattern (not shown) having a predetermined planar shape is formed on the surface of the substrate by utilizing the lithography process. Next, the Ni super-thin film 12 having a thickness of 1 nm, and the Ag electrode 13 having a thickness of 100 nm are formed in order over the entire surface of the substrate by utilizing the vacuum evaporation method. Also, a Ni film, a Pt film, and an Au film are formed in order on the Ag electrode 13 by utilizing the vacuum evaporation method, thereby forming the metallic film 14 for connection composed of the multilayer metallic film having the Ni/Pt/Au structure. Here, a thickness of the Ni film is set as 200 nm, a thickness of the Pt film is set as 50 nm, and a thickness of the Au film is set as 200 nm. A film growth time for the Ni super-thin film 12 is set as 10 seconds. After that, the resist pattern is removed away together with the metallic film formed on the resist pattern (liftoff).

Next, the side of the metallic film 14 for connection having the light emitting diode described above is stuck to a supporting substrate by using an adhesive agent. Although any of various kinds of substrates can be used as the supporting substrate, for example, a sapphire substrate, a silicon substrate or the like can be used.

Next, a laser beam is radiated from an eximer laser or the like to a back surface side of the sapphire substrate to carry out ablation for an interface between the sapphire substrate and the n-type GaN layer, thereby peeling off the sapphire substrate.

Next, a resist pattern (not shown) having a predetermined planar shape is formed on the surface of the n-type semiconductor layer by utilizing the lithography process, and a Ti film, a Pt film, an Au film are formed in order over the entire surface of the n-type semiconductor layer by, for example, utilizing the sputtering method. After that, the resist pattern is removed away together with the Ti film, the Pt film, and the Au film which are formed on the resist pattern (liftoff). As a result, the lower wiring 15 having a predetermined planar shape having the Ti/Pt/Au structure is formed on the n-type GaN cladding layer.

After that, both the supporting substrate and the adhesive agent are removed away.

By successively carrying out the processes described above, the desired GaN system light emitting diode is completed.

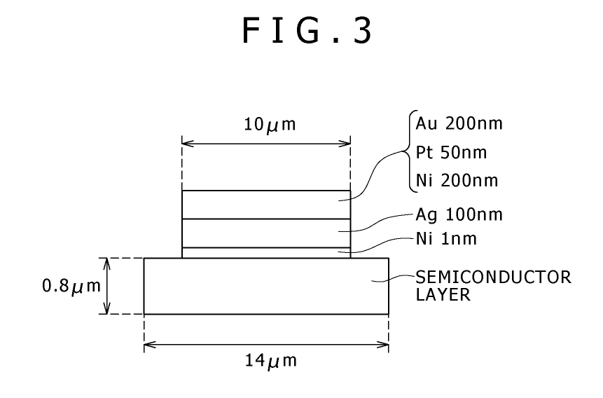

FIG. 3 shows the structure and the size of the GaN system light emitting diode manufactured in the manner described above. The semiconductor layer 11 includes the n-type GaN cladding layer, the active layer having the Ga₁₋ₓInₓN/Ga_{1-y}In_{y}N MQW structure (x=0.18), and has a thickness of about 0.8 μm, a width and a depth of 14 μm, respectively. Also, each of the Ni super-thin film, the Ag electrode, the Ni film, the Pt film, and the Au film has a width and a depth of 10 μm, respectively.

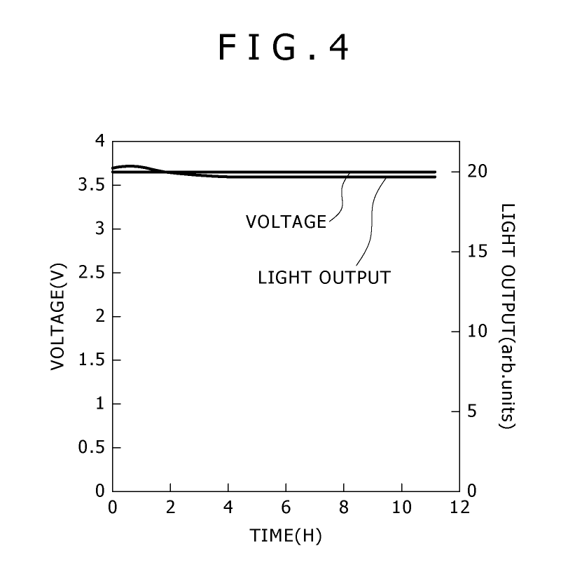

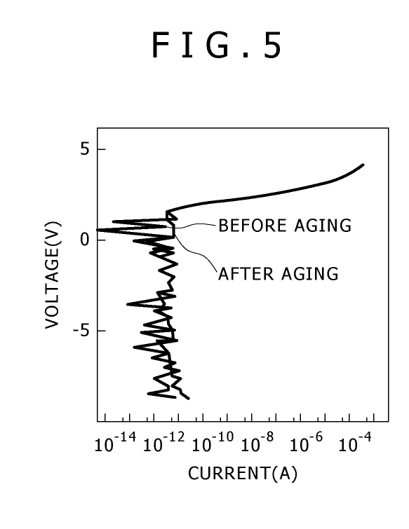

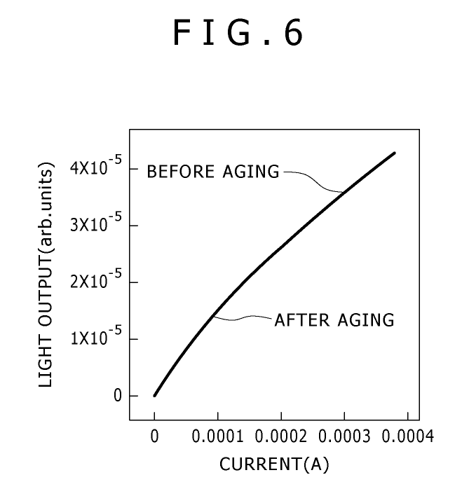

FIG. 4 shows the results of carrying out the aging (a current test in a rated driving at 80° C.) for the GaN system light emitting diode for emitting a blue light manufactured in the manner described above. FIG. 5 shows the results of measuring current-voltage characteristics (I-V characteristics) before and after the aging for the GaN system light emitting diode. Also, FIG. 6 shows the results of measuring current-light output characteristics (I-L characteristics) before and after the aging for the GaN system light emitting diode.

As can be seen from FIGS. 4 to 6, even when the aging is carried out for a time longer than 10 hours, the characteristics of the GaN system light emitting diode hardly change. The reason for this is because the migration of Ag from the Ag electrode 13 is suppressed by the Ni super-thin film 12 formed between the semiconductor layer 11 and the Ag electrode 13.

### Comparative Example

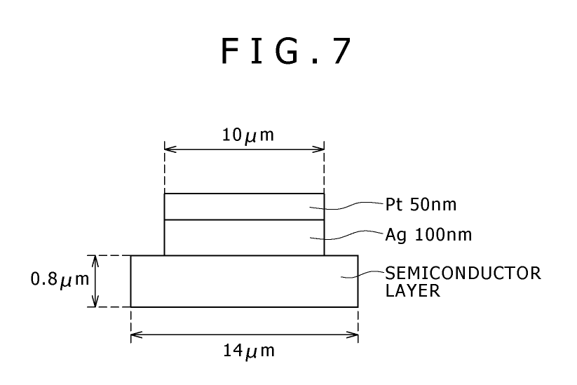

A GaN system light emitting diode having a structure and a size as shown in FIG. 7 was manufactured as a comparative example. As shown in FIG. 7, a semiconductor layer includes an n-type GaN cladding layer, an active layer having a Ga₁₋ₓInₓN/Ga_{1-y}In_{y}N MQW structure (x=0.18), and a p-type GaN cladding layer, and has a thickness of about 0.8 μm, a width and a depth of 14 μm, respectively. Also, an Ag electrode having a thickness of 100 nm, and a Pt film having a thickness of 50 nm were formed in order on the semiconductor layer. Each of the Ag electrode and the Pt film has a width and a depth of 10 μm, respectively.

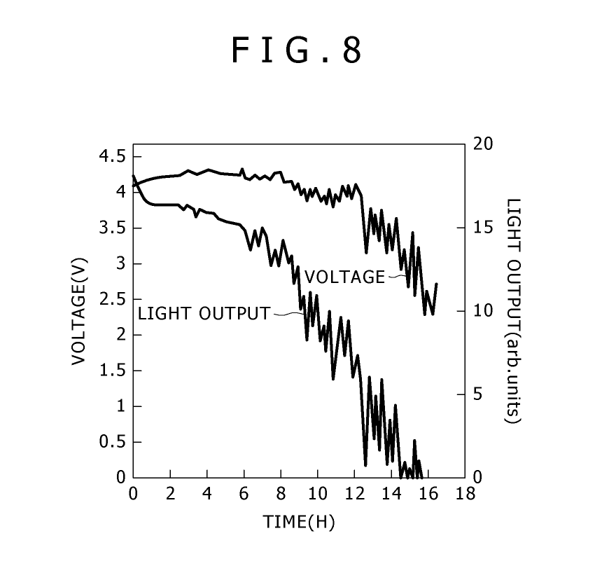

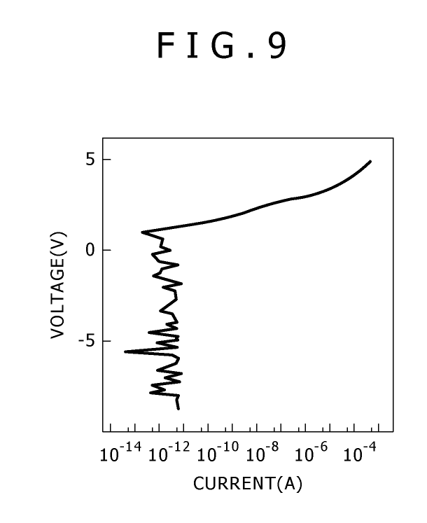

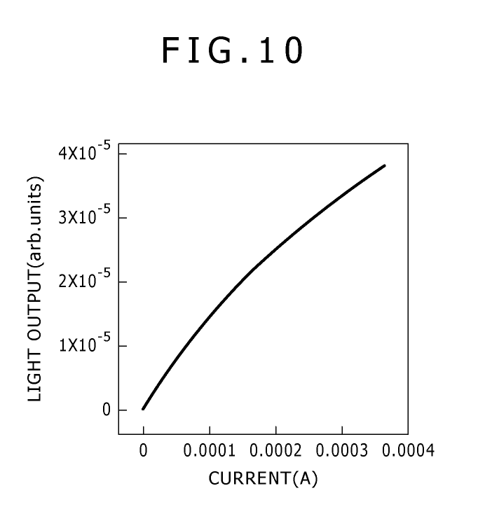

FIG. 8 shows the results of carrying out the aging (the current test in the rated driving at 80° C.) for the GaN system light emitting diode for emitting a blue light manufactured in the manner described above. FIG. 9 shows the results of measuring current-voltage characteristics (I-V characteristics) before the aging for the GaN system light emitting diode. Also, FIG. 10 shows the results of measuring current-light output characteristics (I-L characteristics) before the aging for the GaN system light emitting diode.

As can be seen from FIG. 8, the characteristics of the GaN system light emitting diode become faulty for a short time after start of the aging. With regard to this cause of the fault, it is thought that since the semiconductor layer and the Ag electrode directly contact each other, the migration of the Ag atoms from the Ag electrode is caused, so that the Ag atoms penetrate through the semiconductor layer, or move on the surface of the semiconductor layer.

As described above, according to the first embodiment of the present invention, the Ni super-thin film 12 having the thickness of one atomic layer to 10 nm is formed so as to contact the p-type semiconductor layer of the semiconductor layer 11 forming the GaN system light emitting diode structure, and the Ag electrode 13 is formed on the Ni super-thin film 12. For this reason, the migration of the Ag atoms from the Ag electrode 13 can be effectively prevented from being caused by the Ni super-thin film 12, and thus the short-circuit between the Ag electrode 13 and the lower wiring 15 can be effectively prevented from being caused. In addition thereto, since the Ag electrode 13 is formed on the semiconductor layer 11 through the Ni super-thin film 12, the adhesion property of the Ag electrode 13 to the semiconductor layer 11 can be largely enhanced and the heat-resisting property of the Ag electrode 13 can be greatly enhanced. Moreover, since the Ag electrode 13 can be used without impairing the reflecting property thereof, the light taking-out efficiency can be enhanced, and the light emission efficiency of the GaN system light emitting diode can be enhanced in turn.

In addition, since the protective film made of the barrier metal needs not to be formed as with the related art for the purpose of suppressing the migration of the Ag atoms, not only the lithography process for forming the protective film is unnecessary, but also the process for forming the protective film is unnecessary. For this reason, the processes for manufacturing the GaN system light emitting diode can be simplified all the more, and the manufacture cost can be reduced all the more. In addition, since the protective film needs not to be formed, the size of the Ag electrode 13, that is, the area of the Ag electrode 13 can be made sufficiently large, and thus the quantity of light reflected by the Ag electrode 13 can be made sufficiently much. In addition, since there is no absorption of the light in the contact portion between the protective film and the semiconductor layer 11, the loss of the light caused by the light absorption can be prevented. From these advantages as well, it is possible to enhance the GaN system light emission efficiency of the light emitting diode.

From the above, it is possible to obtain the light emitting diode which has the long life and the high reliability, is inexpensive, and has the excellent characteristics.

The GaN system light emitting diode of the first embodiment is suitable for being used in various kinds of electronic apparatuses such as a light emitting diode display, a light emitting diode backlight, and a light emitting diode lighting system.

### 2. Second Embodiment

[Light Emitting Diode and a Method of Manufacturing the Same]

In a light emitting diode according to a second embodiment of the present invention, the Ni super-thin film 12 is provided so as to contact the semiconductor layer 11 forming the light emitting diode structure, and the Ag electrode 13 and the metallic film 14 for connection are provided in order on the Ni super-thin film 12 through an intermediate metallic layer. The intermediate metallic layer, for example, is made of one, or two or more kinds of metals selected from the group consisting of palladium (Pd), copper (Cu), platinum (Pt), gold (Au), and the like, and may be either a single film or a multilayer film. Although a thickness of the intermediate metallic layer is especially by no means limited and thus is selected as may be necessary, it is preferably made sufficiently thin so as not to impair the reflecting performance of the Ag electrode 13 in view of the metal used. Thus, the thickness of the intermediate metallic layer, for example, is selected in the range of 1 to 10 nm.

The matters of the light emitting diode other than those described above are similar to those of the light emitting diode according to the first embodiment. In addition, the method of manufacturing the light emitting diode is also similar to the method of manufacturing the light emitting diode according to the first embodiment except for the formation of the intermediate metallic layer.

According to a second embodiment, it is possible to obtain the same effects as those in the first embodiment.

Although the first and second embodiments, and the example of the first embodiment of the present application have been concretely described so far, the present application is by no means limited to the first and second embodiments, and the example of the first embodiment described above, and thus the various kinds of changes based on the technical idea of the present application can be made.

For example, the numerical values, the structures, the constitutions, the shapes, the materials, and the like which are given in the first and second embodiments, and the example of the first embodiment described above are merely examples, and thus numerical values, structures, constitutions, shapes, materials, and the like which are different from those may also be used as may be necessary.

In addition, in each of the GaN system light emitting diodes of the first and second embodiments, a protective film (cover metal) made of the existing known metal may be used in combination therewith. As a result, the reliability of the GaN system light emitting diode can be further enhanced.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A method of manufacturing a semiconductor light emitting element, comprising:
forming a nickel thin film having a thickness of one atomic layer to 10 nm so as to contact a semiconductor layer forming a light emitting element structure; and
forming a silver electrode on said nickel thin film.

2. The method of manufacturing a semiconductor light emitting element according to claim 1, wherein a thickness of said nickel thin film is equal to or smaller than 2 nm.

3. The method of manufacturing a semiconductor light emitting element according to claim 2, wherein a thickness of said nickel thin film is equal to or smaller than 1 nm.

4. The method of manufacturing a semiconductor light emitting element according to claim 1, wherein said semiconductor layer is a nitride system III-V compound semiconductor layer.

5. The method of manufacturing a semiconductor light emitting element according to claim 1, wherein said semiconductor layer includes an n-type semiconductor layer, an active layer, and a p-type semiconductor layer, and said nickel thin film is formed so as to contact said p-type semiconductor layer.

6. The method of manufacturing a semiconductor light emitting element according to claim 1, wherein said semiconductor light emitting element is a light emitting diode.

7. A semiconductor light emitting element, comprising:
a semiconductor layer forming a light emitting element structure;
a nickel thin film having a thickness of one atomic layer to 10 nm and contacting said semiconductor layer; and
a silver electrode formed on said nickel thin film.

8. The semiconductor light emitting element according to claim 7, wherein a thickness of said nickel thin film is equal to or smaller than 2 nm.

9. The semiconductor light emitting element according to claim 8, wherein a thickness of said nickel thin film is equal to or smaller than 1 nm.

10. The semiconductor light emitting element according to claim 7, wherein said semiconductor layer is a nitride system III-V compound semiconductor layer.

11. The semiconductor light emitting element according to claim 7, wherein said semiconductor layer includes an n-type semiconductor layer, an active layer, and a p-type semiconductor layer, and said nickel thin film is formed so as to contact said p-type semiconductor layer.

12. The semiconductor light emitting element according to claim 7, wherein said semiconductor light emitting element is a light emitting diode.

13. A method of manufacturing a semiconductor element, comprising:
forming a nickel thin film having a thickness of one atomic layer to 10 nm so as to contact a semiconductor layer forming an element structure; and
forming a silver electrode on said nickel thin film.

14. A semiconductor element, comprising:
a semiconductor layer forming an element structure;
a nickel thin film having a thickness of one atomic layer to 10 nm and contacting said semiconductor layer; and
a silver electrode formed on said nickel thin film.
